(19) United States
(12) Patent Application Publication
(10) Pub. No.: US 2025/0201291 A1
(43) Pub. Date: Jun. 19, 2025

(54) MAGNETIC MEMORY DEVICE AND METHOD OF FABRICATING THE SAME

(71) Applicant: Industrial Technology Research Institute, Hsinchu (TW)

(72) Inventors: Hsin-Han Lee, Hsinchu City (TW); Jeng-Hua Wei, Taipei City (TW); I-Jung Wang, Hsinchu City (TW); Kuan-Ming Chen, Tainan City (TW)

(73) Assignee: Industrial Technology Research Institute, Hsinchu (TW)

(21) Appl. No.: 18/759,997

(22) Filed: Jun. 30, 2024

(30) Foreign Application Priority Data
Dec. 18, 2023 (TW) 112149310

(51) Int. Cl. G11C 11/16; H10B 61/00; H10N 50/01; H10N 50/10; H10N 50/80

(52) U.S. Cl. CPC G11C 11/161; H10B 61/00; H10N 50/01; H10N 50/10; H10N 50/80; G11C 11/1673; G11C 11/1675

(57) ABSTRACT

A magnetic memory device includes multiple perpendicular spin-orbit torque (SOT) elements and multiple stray field applying layers. Each of the perpendicular SOT elements at least includes a first electrode, a second electrode, and a magnetic tunnel junction (MTJ). The MTJ is disposed on the first electrode, and the second electrode is disposed on the MTJ. The stray field applying layers are disposed between the perpendicular SOT elements, and each of the stray field applying layers extends horizontally between the first electrode and the second electrode. These layers generate the magnetic field required to flip the free layer during SOT, eliminating the need for an additional magnetic field during reading and writing. Additionally, the stray field applying layer horizontally disposed on two sides of the MTJ doesn't increase device height, allowing reduction of write current without increasing the read current resistance, thus reducing the power consumption.

### CROSS-REFERENCE TO RELATED APPLICATION

This application claims the priority benefit of Taiwan application serial no. 112149310, filed on Dec. 18, 2023. The entirety of the above-mentioned patent application is hereby incorporated by reference herein and made a part of this specification.

### BACKGROUND

### Technical Field

This disclosure relates to a magnetic memory device and a method of fabricating the same.

### Description of Related Art

Magnetic random access memory (MRAM) offers the advantages of high speed, low power consumption, high density, non-volatility, and virtually unlimited read/write cycles. The mechanism of magnetic tunnel junction device to read/write by Spin-Orbit-Torque (SOT) is that a current flowing into a heavy metal layer generates SOT at the interface, and the resultant moment of the external magnetic field H will flip the magnetic moment perpendicular to film surface in the ferromagnetic material at the interface, which is regarded as a new generation of memory read/write mechanism.

However, since memory operation requires an external magnetic field, additional devices or power consumption are required. There have been studies on stacking various magnetic functional layers in SOT magnetic memory devices to replace the external magnetic field, but this increases the overall resistance of the devices, leading to an increase in the operating current, which is not favorable for the development of high-performance magnetic memories.

### SUMMARY

The disclosure provides a magnetic memory device and a method of fabricating the same, capable of achieving SOT flip without the use of an external magnetic field, and capable of lowering an operating current of an element.

A magnetic memory device according to various embodiments of the disclosure includes multiple perpendicular spin-orbit torque elements and multiple stray field applying layers. Each of the perpendicular spin-orbit torque elements at least includes a first electrode, a second electrode, and a magnetic tunnel junction (MTJ). The magnetic tunnel junction is disposed on the first electrode, and the second electrode is disposed on the magnetic tunnel junction. The stray field applying layers are disposed between the perpendicular spin-orbit torque elements, and each of the stray field applying layers extends horizontally between the first electrode and the second electrode.

A method of fabricating a magnetic memory device according to various embodiments of the disclosure includes the following. A first electrode is formed. A magnetic tunnel junction (MTJ) is formed on the first electrode. A dielectric layer is formed to simultaneously cover the first electrode and the magnetic tunnel junction. Multiple stray field applying layers are formed on the dielectric layer on two sides of the magnetic tunnel junction respectively. A second electrode electrically connected to the magnetic tunnel junction are formed on the stray field applying layers.

The device and method of the disclosure are to dispose the stray field applying layers on two sides of the MTJ, so that SOT flip may be performed without an external magnetic field. Since the position of the stray field applying layer does not overlap with the MTJ, a write current of the magnetic memory device may be reduced without increasing resistance of a read current.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a schematic cross-sectional view of a magnetic memory device according to A first embodiment of the disclosure.

FIG. 2A is a schematic view of the magnetic memory device of FIG. 1.

FIG. 2B is a plan view of the magnetic memory device of FIG. 2A.

FIG. 3A to FIG. 3D are schematic cross-sectional views of a fabricating process of a magnetic memory device according to a second embodiment of the disclosure.

FIG. 4 is a schematic cross-sectional view of a magnetic memory device according to a third embodiment of the disclosure.

FIG. 5A is a schematic view of the magnetic memory device of FIG. 4.

FIG. 5B is a plan view of the magnetic memory device of FIG. 5A.

FIG. 6A to FIG. 6D are schematic cross-sectional views of a fabricating process of a magnetic memory device according to a fourth embodiment of the disclosure.

### DESCRIPTION OF THE EMBODIMENTS

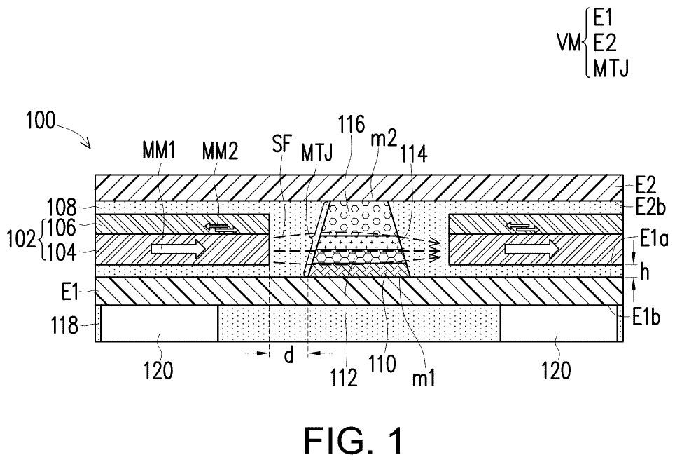

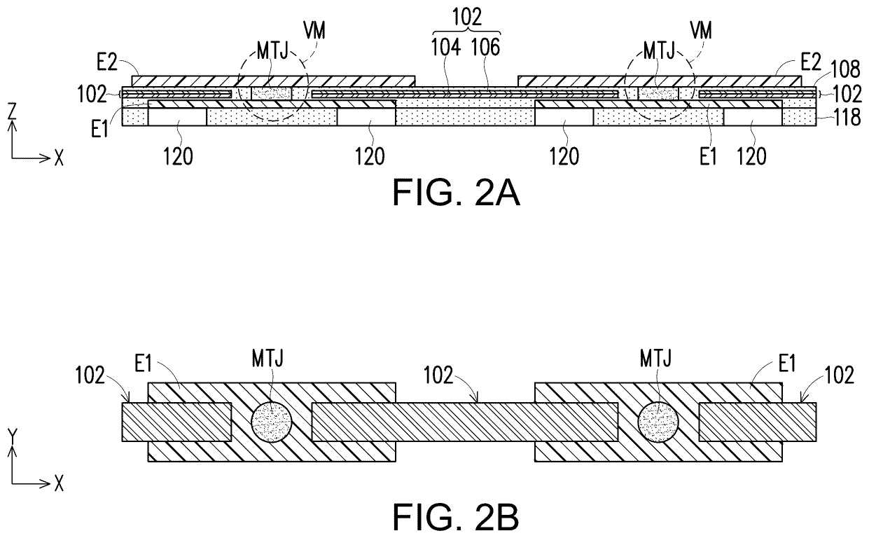

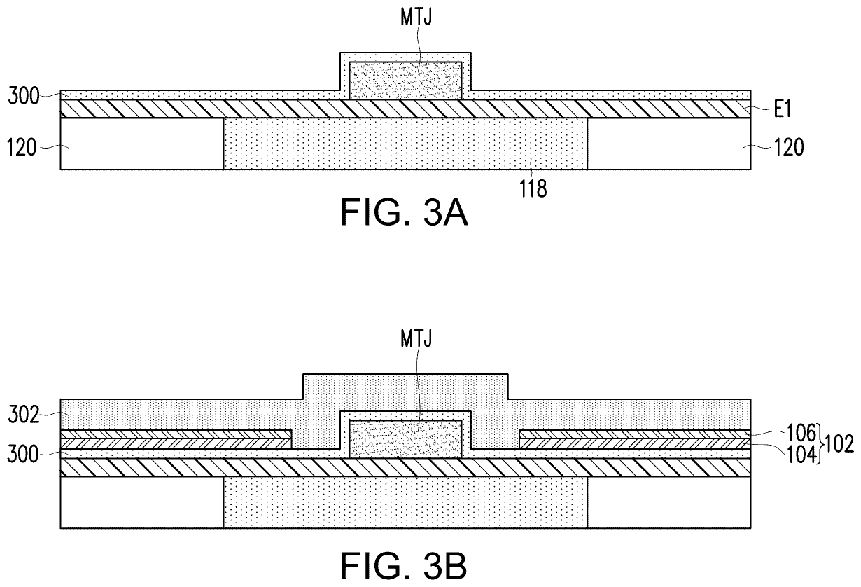

FIG. 1 is a schematic cross-sectional view of a magnetic memory device according to A first embodiment of the disclosure. FIG. 2A is a schematic view of the magnetic memory device of FIG. 1. FIG. 2B is a plan view of the magnetic memory device of FIG. 2A, in which some components are omitted.

Referring to FIG. 1 and FIG. 2A, a magnetic memory device 100 of the first embodiment includes multiple perpendicular spin-orbit torque elements VM and multiple stray field applying layers 102. FIG. 1 shows the detailed structure of a single perpendicular spin-orbit torque element VM and a magnetic tunnel junction MTJ therein, while FIG. 2A shows two perpendicular spin-orbit torque elements VM with the position of the magnetic tunnel junction MTJ simply indicated by a rectangle. The perpendicular spin-orbit torque element VM may save more than 50% of area compared to a conventional horizontal spin-orbit torque element.

In FIG. 1, the perpendicular spin-orbit torque element VM includes a first electrode E1, a magnetic tunnel junction MTJ, and a second electrode E2. The magnetic tunnel junction MTJ is disposed on the first electrode E1, and the second electrode E2 is disposed on the magnetic tunnel junction MTJ. In some embodiments, the material of the first electrode E1 may include, but is not limited to, tantalum (Ta), platinum (Pt), tungsten (W), titanium (Ti), or a single-layer or multi-layer structure of a combination of the foregoing. In some embodiments, the material of the second electrode E2 is, for example, but not limited to, copper (Cu), platinum (Pt), tungsten (W), or a combination of the foregoing. The stray field applying layers 102 are disposed between the perpendicular spin-orbit torque elements VM, and each of the stray field applying layers 102 extends horizontally between the first electrode E1 and the second electrode E2.

In the magnetic memory device 100 of the first embodiment, the each of the stray field applying layers 102 may includes a ferromagnetic layer 104 and an antiferromagnetic layer 106. The ferromagnetic layer 104 extends horizontally between the first electrode E1 and the second electrode E2, and the antiferromagnetic layer 106 also extends horizontally between the first electrode E1 and the second electrode E2. A magnetic moment MM1 of the ferromagnetic layer 104 and a magnetic moment MM2 of the antiferromagnetic layer 106 are shown in FIG. 1. The antiferromagnetic layer 106 fixes the axial direction of the magnetic moment MM1 of the lower ferromagnetic layer 104, so that a stable and sufficient stray field SF is formed between the stray field applying layers 102. A SOT flip operation may be achieved through the stray field SF without an external magnetic field, so that the power consumption may be reduced. In order to enable the antiferromagnetic layer 106 to fix the axial direction of the magnetic moment, the antiferromagnetic layer 106 may be subjected to a magnetic annealing process at a predetermined temperature to fix the direction of the magnetic moment MM1 generated by the ferromagnetic layer 104 by the antiferromagnetic layer 106. In some embodiments, the material of the ferromagnetic layer 104 may be iron (Fe), cobalt (Co), nickel (Ni), gallium (Gd), terium (Tb), dysprosium (Dy), boron (B) or alloys of the aforementioned elements. In some embodiments, the material of the antiferromagnetic layer 106 may be platinum manganese (PtMn), manganese oxide (MnO), ferromanganese (IrMn), chromium oxide (CrO) or a combination of the foregoing. In one embodiment, a vertical distance h between the stray field applying layer 102 and the first electrode E1 is, for example, between 200 Angstroms (Å) and 600 Angstroms (Å), but the disclosure is not limited thereto. The vertical distance h may increase or decrease depending on the size, materials, and characteristics of the various components in the magnetic memory device 100. In one embodiment, from the perspective of magnetic field stability, a horizontal distance d between the stray field applying layer 102 and the magnetic tunnel junction MTJ is, for example, between 200 Å and 600 Å, but the disclosure is not limited thereto. In some embodiments, the horizontal distance d is greater than the vertical distance h.

Please continue to refer to FIG. 1. The magnetic memory device 100 further has a dielectric layer 108, which is between the first electrode E1 and the second electrode E2 and separates the stray field applying layer 102 and the magnetic tunnel junction MTJ. The magnetic tunnel junction MTJ may include a free layer 110, a barrier layer 112, a pinned layer 114, and a metal covering layer 116. The barrier layer 112 is formed on the free layer 110, the pinned layer 114 is formed on the barrier layer 112, and the metal covering layer 116 is formed on the pinned layer 114. In the first embodiment, a lower surface m1 of the magnetic tunnel junction MTJ is attached to an upper surface Ela of the first electrode E1, and an upper surface m2 of the magnetic tunnel junction MTJ is attached to a lower surface E2b of the second electrode E2, but the disclosure is not limited thereto. In another embodiment, other functional layers may be disposed between the lower surface m1 of the magnetic tunnel junction MTJ and the first electrode E1; alternatively, other functional layers may be disposed between the upper surface m2 of the magnetic tunnel junction MTJ and the second electrode E2.

In some embodiments, the material of the free layer 110 is a ferromagnetic material with perpendicular anisotropy, so that the magnetic moment flip in the magnetic film layer may be utilized for data reading, and therefore the ferromagnetic material of the free layer 110 may be, but not limited to, iron (Fe), cobalt (Co), nickel (Ni), gallium (Gd), dynamium (Tb), dysprosium (Dy), boron (B) or alloys of the aforementioned elements, such as CoFeB, NiFe, FeB. The free layer 110 may be a single-layer structure or a multi-layer structure. In one embodiment, the free layer is composed of multi-layer ferromagnetic materials, and the multi-layer ferromagnetic materials may be a composite layer structure composed of elements such as cobalt (Co)/platinum (Pt), cobalt (Co)/nickel (Ni), cobalt (Co)/palladium (Pd) and so on, but the disclosure is not limited thereto.

In some embodiments, the barrier layer 112 is an insulating material with magnetic tunnel conditions at a specific thickness. The insulating materials may be magnesium oxide, aluminum oxide, or a combination of the foregoing.

In some embodiments, the pinned layer 114 refers to a multi-layer structure that is not subject to change by operating magnetic fields or other conditions. In one embodiment, the pinned layer 114 may consist of two layers of ferromagnetic material (not shown) with opposite magnetic moment vectors at the top and bottom and perpendicular to the film surface, and a non-magnetic metal (not shown) sandwiched in between. In one embodiment, the two layers of ferromagnetic material are perpendicularly anisotropic and may be single-layer or multi-layer structures. Available ferromagnetic materials may refer to the ferromagnetic material of the free layer 110. The non-magnetic metal sandwiched in between may be ruthenium (Ru), copper (Cu), iridium (Ir), tantalum (Ta), platinum (Pt), tungsten (W), magnesium (Mg), etc.

In some embodiments, a material of the metal covering layer 116 is, for example, but not limited to, titanium nitride (TiN), tantalum nitride (TaN), titanium (Ti), tantalum (Ta), or a combination of the foregoing.

In addition, below the first electrode E1, there is usually an insulating layer 118 and an electrode channel 120 formed inside the insulating layer 118. The lower surface E1b of the first electrode E1 may be in direct contact with the electrode channel 120, and a front-end circuit (not shown) may be disposed below the insulating layer 118 for application in various precision components.

Please continue to refer to FIG. 2A and FIG. 2B. Since the stray field applying layer 102 itself is not electrically connected to the first electrode E1, the magnetic tunnel junction MTJ, and the second electrode E2, two adjacent perpendicular spin-orbit torque elements VM may share one stray field applying layer 102. More specifically, the structure of the magnetic tunnel junction MTJ does not require the insertion of other film layers to adjust the magnetic moment of the free layer 110, so the overall height of the perpendicular spin-orbit torque element VM is lowered and the write current is reduced.

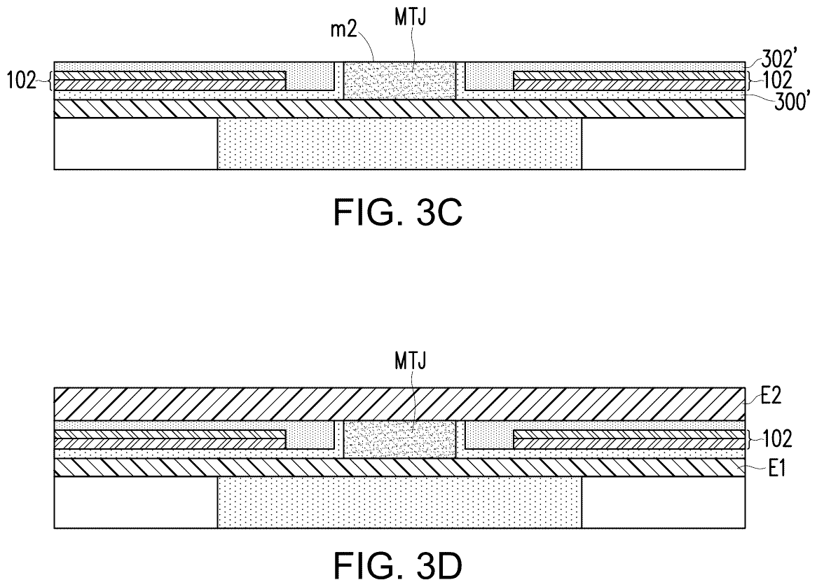

FIG. 3A to FIG. 3D are schematic cross-sectional views of a fabricating process of a magnetic memory device according to a second embodiment of the disclosure, where the same numeral references as those in the first embodiment are used to represent the same or similar parts and components, and the relevant content of the same or similar parts and components may also be referred to the contents of the first embodiment, which will not be repeated in the following.

Referring to FIG. 3A, a fabricating method of the second embodiment may begin with the formation of the first electrode E1. For example, the front-end circuit is completed first, and then the insulating layer 118 and the electrode channel 120 are formed. Then, the magnetic tunnel junction MTJ is formed on the first electrode E1. A method of forming the magnetic tunnel junction MTJ is, for example, depositing a stacked structure (not shown) on the first electrode E1, performing magnetic annealing on the stacked structure in a direction perpendicular to the film surface, and then etching the stacked structure until the first electrode E1 is exposed. In one embodiment, the magnetic annealing in the direction perpendicular to the film surface may be performed at a temperature between about 300° C. and about 400° C. for a period of about 0.3 to 4 hours, and a magnetic field in the direction perpendicular to the film surface may be applied at the same time during this magnetic annealing period to further increase the magnetic anisotropy in the perpendicular direction. During the magnetic annealing period, the magnetic field may be between approximately 1 tesla and 5 tesla. The detailed structure of the magnetic tunnel junction MTJ may be referred to FIG. 1A, or a known magnetic tunnel junction MTJ may be used. Then, a dielectric layer 300 is formed to simultaneously cover the first electrode E1 and the magnetic tunnel junction MTJ.

Then, referring to FIG. 3B, the stray field applying layers 102 are formed on the dielectric layer 300 on two sides of the magnetic tunnel junction MTJ respectively. A method of forming the stray field applying layer 102 is, for example, forming the ferromagnetic layer 104 on the dielectric layer 300 first, forming the antiferromagnetic layer 106 on the ferromagnetic layer 104, and then etching the antiferromagnetic layer 106 and the ferromagnetic layer 104 until the dielectric layer 300 is exposed. The materials of the ferromagnetic layer 104 and the antiferromagnetic layer 106 may be referred to the description in the first embodiment, and therefore will not be repeated in the following. After that, a capping layer 302 is formed to cover the stray field applying layer 102, where the capping layer 302 is a dielectric material, and may be the same or different material as the dielectric layer 300.

Subsequently, referring to FIG. 3C, the capping layer 302 and the dielectric layer 300 in FIG. 3B is etched back to expose the upper surface m2 of the magnetic tunnel junction MTJ. After etching back, a top surface of a capping layer 302′ and a top surface of a dielectric layer 300′ will be flush with or slightly below the upper surface m2 of the magnetic tunnel junction MTJ.

Then, referring to FIG. 3D, a second electrode E2 electrically connected to the magnetic tunnel junction MTJ is formed on the stray field applying layer 102. In one embodiment, magnetic annealing in the horizontal direction may be performed after the second electrode E2 is formed. The magnetic annealing in the horizontal direction may be performed at a temperature between about 300° C. and about 400° C. for a period of about 0.3 to 4 hours, and a magnetic field in the horizontal direction may be applied at the same time during the magnetic annealing period to further increase the magnetic anisotropy in the horizontal direction. During the magnetic annealing period in the horizontal direction, the applied magnetic field may be between approximately 1 tesla and 5 tesla.

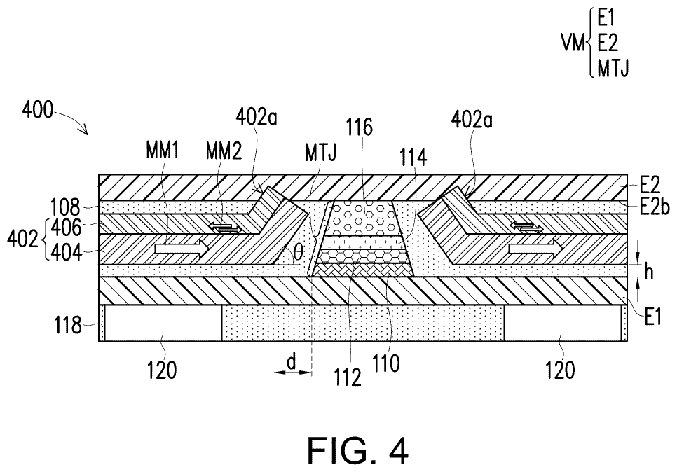

FIG. 4 is a schematic cross-sectional view of a magnetic memory device according to a third embodiment of the disclosure, where the same numeral references as those in the first embodiment are used to represent the same or similar parts and components, and the relevant content of the same or similar parts and components may also be referred to the contents of the first embodiment, which will not be repeated in the following.

Referring to FIG. 4, the difference between a magnetic memory device 400 of the third embodiment and the first embodiment is that the magnetic memory device 400 includes multiple perpendicular spin-orbit torque elements VM and multiple stray field applying layers 402. In addition to extending horizontally between the first electrode E1 and the second electrode E2, a ferromagnetic layer 404 and an antiferromagnetic layer 406 of the stray field applying layer 402 further include an extension portion 402a. The extension portion 402a is adjacent to the magnetic tunnel junction MTJ and extends upward into the second electrode E2, for example, the antiferromagnetic layer 406 is in direct contact with the lower surface E2b of the second electrode E2, or even the ferromagnetic layer 404 is in direct contact with the lower surface E2b of the second electrode E2, but the disclosure is not limited thereto.

In one embodiment, an angle θ between a direction in which the extension portion 402a extends upward into the second electrode E2 and the horizontal direction is greater than 50° and less than 80°, but the disclosure is not limited thereto. In some embodiments, a horizontal distance d between the stray field applying layer 402 and the magnetic tunnel junction MTJ is, for example, between 200 Å and 600 Å, but the disclosure is not limited thereto. In some embodiments, the horizontal distance d in FIG. 4 refers to the distance between the part of the stray field applying layer 402 that is closest to the magnetic tunnel junction MTJ, except for the extension portion 402a, and the magnetic tunnel junction MTJ. In some embodiments, a vertical distance h between the stray field applying layer 402 and the first electrode E1 may be between 200 Å and 600 Å, but the disclosure is not limited thereto. In some embodiments, the horizontal distance d is greater than the vertical distance h.

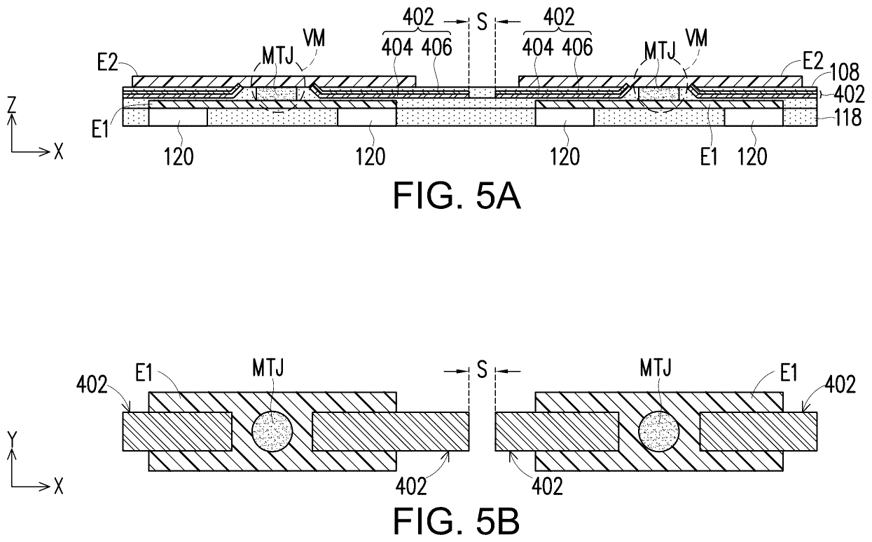

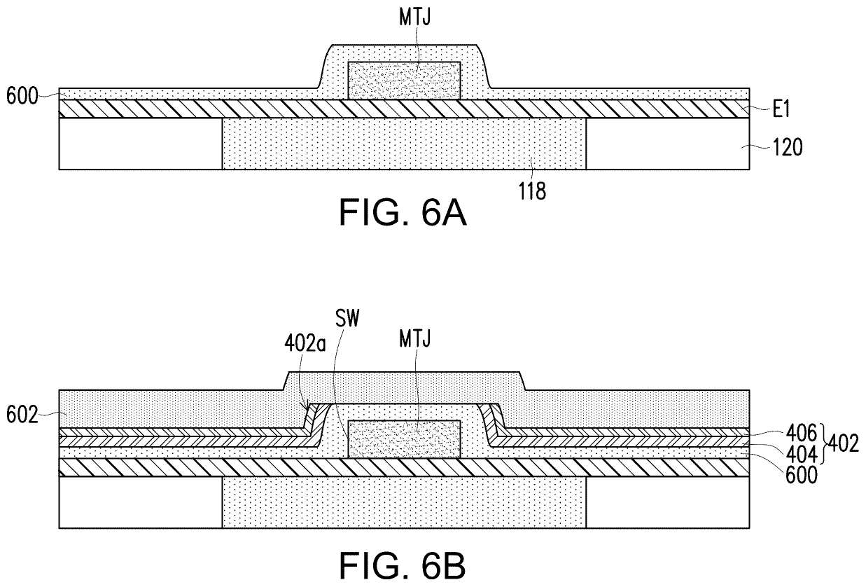

FIG. 5A is a schematic view of the magnetic memory device of FIG. 4, showing two perpendicular spin-orbit torque elements VM but with the position of the magnetic tunnel junction MTJ simply indicated by a rectangle, and each of the stray field applying layers 402 extends horizontally between the first electrode E1 and the second electrode E2. FIG. 5B is a plan view of the magnetic memory device of FIG. 5A, showing only the first electrode E1, the magnetic tunnel junction MTJ, and the stray field applying layer 402.

Please refer to FIG. 5A and FIG. 5B at the same time. Since the extension portion 402a of the stray field applying layer 402 extends upward into the second electrode E2, two stray field applying layers 402 separated from each other are between two adjacent perpendicular spin-orbit torque elements VM. In one embodiment, a distance S between the two stray field applying layers 402 separated from each other is greater than 0.1 μm. However, the disclosure is not limited thereto. The distance S may increase or decrease depending on the size, materials, and characteristics of the various components in the magnetic memory device 400 of FIG. 4.

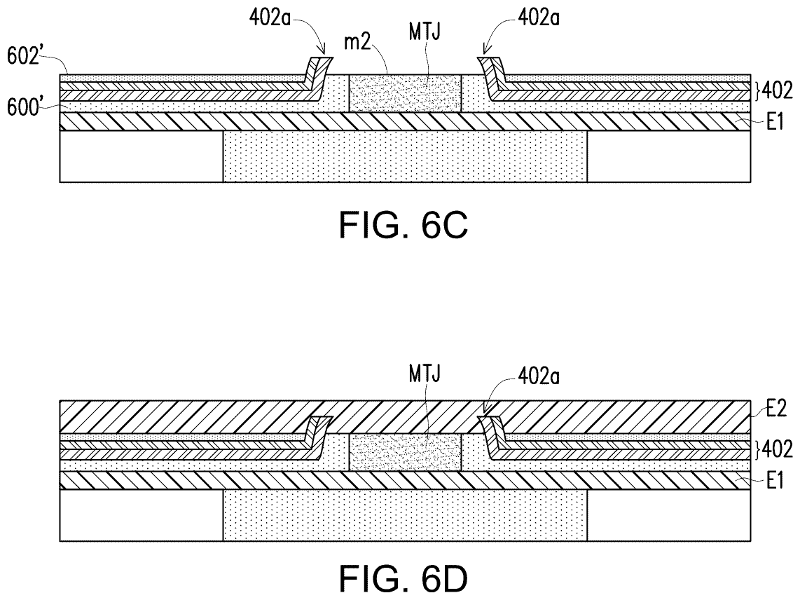

FIG. 6A to FIG. 6D are schematic cross-sectional views of a fabricating process of a magnetic memory device according to a fourth embodiment of the disclosure, where the same numeral references as those in the third embodiment are used to represent the same or similar parts and components, and the relevant content of the same or similar parts and components may also be referred to the contents of the third embodiment, which will not be repeated in the following.

Please refer to FIG. 6A first. A fabricating method of the fourth embodiment may begin with the formation of the first electrode E1. For example, the front-end circuit is completed first, and then the insulating layer 118 and the electrode channel 120 are formed. Then, the magnetic tunnel junction MTJ is formed on the first electrode E1. A method of forming the magnetic tunnel junction MTJ is, for example, depositing a stacked structure (not shown) on the first electrode E1, performing magnetic annealing on the stacked structure in a direction perpendicular to the film surface, and then etching the stacked structure until the first electrode E1 is exposed. The magnetic annealing in the direction perpendicular to the film surface may be referred to the relevant description of the second embodiment, and therefore will not be repeated the following. Then, a dielectric layer 600 is formed to simultaneously cover the first electrode E1 and the magnetic tunnel junction MTJ.

Next, referring to FIG. 6B, the stray field applying layers 402 are respectively formed on the dielectric layer 600 on two sides of the magnetic tunnel junction MTJ. A method of forming the stray field applying layer 402 is, for example, forming the ferromagnetic layer 404 on the dielectric layer 600 first, forming the antiferromagnetic layer 406 on the ferromagnetic layer 404, and then etching the antiferromagnetic layer 406 and the ferromagnetic layer 404 until the dielectric layer 600 is exposed while retaining a part next to a side wall SW of the magnetic tunnel junction MTJ as the extension portion 402a. The materials of the ferromagnetic layer 404 and the antiferromagnetic layer 404 may refer to the ferromagnetic layer 104 and the antiferromagnetic layer 104 in the first embodiment, and will not be repeated in the following. After that, a capping layer 602 is formed to cover the stray field applying layer 402, where the capping layer 602 is a dielectric material, and may be the same or different material as the dielectric layer 600.

Then, referring to FIG. 6C, the capping layer 602 and the dielectric layer 600 in FIG. 6B are etched back to expose the upper surface m2 of the magnetic tunnel junction MTJ. After etching back, top surfaces of a capping layer 602′ and a dielectric layer 600′ will be flush with or slightly lower than the upper surface m2 of the magnetic tunnel junction MTJ.

After that, referring to FIG. 6D, a second electrode E2 electrically connected to the magnetic tunnel junction MTJ is formed on the stray field applying layer 402. In one embodiment, magnetic annealing in the horizontal direction may be performed after the second electrode E2 is formed. The magnetic annealing in the horizontal direction may be referred to the relevant description of the second embodiment, and therefore will not be repeated in the following.

To sum up, in the disclosure, the stray field applying layer extending horizontally between the two electrodes generates the magnetic field required to flip the free layer during SOT, thus eliminating the need for an additional magnetic field during reading and writing. Moreover, the stray field applying layer horizontally disposed on two sides of the magnetic tunnel junction does not increase the height of the magnetic memory device, so the write current of the magnetic memory device may be reduced without increasing the resistance of the read current, thus reducing the operating power consumption.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A magnetic memory device, comprising:
a plurality of perpendicular spin-orbit torque elements, each of the perpendicular spin-orbit torque elements comprising:
a first electrode;
a magnetic tunnel junction (MTJ), disposed on the first electrode; and
a second electrode, disposed on the magnetic tunnel junction; and
a plurality of stray field applying layers, disposed between the perpendicular spin-orbit torque elements, and each of the stray field applying layers extending horizontally between the first electrode and the second electrode.

2. The magnetic memory device according to claim 1, wherein the each of the stray field applying layers comprises a ferromagnetic layer and an antiferromagnetic layer, the ferromagnetic layer extends horizontally between the first electrode and the second electrode, and the antiferromagnetic layer extends horizontally between the first electrode and the second electrode.

3. The magnetic memory device according to claim 1, wherein a vertical distance between the stray field applying layer and the first electrode is between 200 angstroms (Å) and 600 angstroms (Å).

4. The magnetic memory device according to claim 1, wherein a horizontal distance between the stray field applying layer and the magnetic tunnel junction is between 200 angstroms (Å) and 600 angstroms (Å).

5. The magnetic memory device according to claim 1, wherein a horizontal distance between the stray field applying layer and the first electrode is greater than a vertical distance between the stray field applying layer and the first electrode.

6. The magnetic memory device according to claim 1, wherein two adjacent ones of the perpendicular spin-orbit torque elements share one of the stray field applying layers.

7. The magnetic memory device according to claim 1, wherein the each of the stray field applying layers comprises an extension portion adjacent to the magnetic tunnel junction and extending upward into the second electrode.

8. The magnetic memory device according to claim 7, wherein an angle between a direction in which the extension portion extends upward into the second electrode and a horizontal direction is greater than 50° and less than 80°.

9. The magnetic memory device according to claim 8, wherein two of the stray field applying layers separated from each other are between two adjacent ones of the perpendicular spin-orbit torque elements.

10. The magnetic memory device according to claim 9, wherein a distance between the two of the stray field applying layers separated from each other is greater than 0.1 μm.

11. The magnetic memory device according to claim 1, wherein the magnetic tunnel junction comprises:
a free layer;
a barrier layer, formed on the free layer;
a pinned layer, formed on the barrier layer; and
a metal covering layer, formed on the pinned layer.

12. The magnetic memory device according to claim 1, wherein a lower surface of the magnetic tunnel junction is attached to an upper surface of the first electrode, and an upper surface of the magnetic tunnel junction is attached to a lower surface of the second electrode.

13. The magnetic memory device according to claim 1, further comprising a dielectric layer located between the first electrode and the second electrode and separating the magnetic tunnel junction of the perpendicular spin-orbit torque elements and the stray field applying layers.

14. A method of fabricating a magnetic memory device, comprising:
forming a first electrode;
forming a magnetic tunnel junction (MTJ) on the first electrode;
forming a dielectric layer to simultaneously cover the first electrode and the magnetic tunnel junction;
forming a plurality of stray field applying layers on the dielectric layer on two sides of the magnetic tunnel junction respectively; and
forming a second electrode electrically connected to the magnetic tunnel junction on the stray field applying layers.

15. The method of fabricating the magnetic memory device according to claim 14, wherein a method of forming the magnetic tunnel junction comprises:
depositing a stacked structure on the first electrode;
performing magnetic annealing on the stacked structure in a direction perpendicular to a film surface; and
etching the stacked structure until the first electrode is exposed.

16. The method of fabricating the magnetic memory device according to claim 14, wherein each of the stray field applying layers comprises an extension portion formed next to a side wall of the magnetic tunnel junction.

17. The method of fabricating the magnetic memory device according to claim 14, wherein a method of forming the stray field applying layers comprises:
forming a ferromagnetic layer on the dielectric layer;
forming an antiferromagnetic layer on the ferromagnetic layer; and
etching the antiferromagnetic layer and the ferromagnetic layer until the dielectric layer is exposed.

18. The method of fabricating the magnetic memory device according to claim 14, wherein before forming the second electrode further comprises:
forming a capping layer to cover the stray field applying layers; and
etching back the capping layer and the dielectric layer to expose an upper surface of the magnetic tunnel junction.

19. The method of fabricating the magnetic memory device according to claim 14, wherein after forming the second electrode further comprises performing magnetic annealing in a horizontal direction.
